(19) United States
(12) Patent Application Publication
(10) Pub. No.: US 2008/0129369 A1
(43) Pub. Date: Jun. 5, 2008

(54) CURRENT MULTIPLEXING CIRCUIT FOR OPTICAL POWER MONITORING

(76) Inventors: Dusan Ivancevic, Ottawa (CA); Srikanth Ramakrishnan, Ottawa (CA)

Correspondence Address: Teitelbaum & MacLean, 280 Sunnyside Avenue, Ottawa, ON, K1S 0R8, omitted

(21) Appl. No.: 11/923,199

(22) Filed: Oct. 24, 2007

Related U.S. Application Data
(60) Provisional application No. 60/854,423, filed on Oct. 26, 2006.

(51) Int. Cl. H03K 17/00

(52) U.S. Cl. 327/410; 327/407

(57) ABSTRACT

The invention provides a current multiplexing circuit for time-domain multiplexing a plurality of current signals such as photocurrents that are received in a plurality of input terminals. The current signals are multiplexed using one or more analog low-resistance switches operational to connect each of the input terminals to an output switch terminal at a time in a selected sequence, while coupling the other input terminals and the output switch terminal to a reference potential such as ground. The current multiplexing circuit can be used in an optical power monitor with auto-calibration functionality for monitoring a plurality of optical signals.

### CROSS-REFERENCE TO RELATED APPLICATIONS

The present invention claims priority from U.S. Provisional Patent Application No. 60/854,423 filed Oct. 26, 2006, entitled “Method of measuring multiplexed photocurrents using analog CMOS switch”, which is incorporated herein by reference for all purposes.

### TECHNICAL FIELD

The present invention generally relates to a circuit and method for multiplexing electrical currents, and particularly relates to an optical power monitor utilizing direct photocurrent multiplexing for monitoring a plurality of optical signals.

### BACKGROUND OF THE INVENTION

Optical communication systems often require monitoring of optical power in a plurality of optical channels. One example of optical systems where such multi-channel optical power monitors are typically called for are optical add-drop multiplexers (OADM) installed at optical network nodes. A typical OADM includes a plurality of optical taps for tapping optical power of de-multiplexed channels to be received by an associated plurality of photodetectors. The photodetectors generate photocurrents that have to be analyzed to assess the presence of an optical signal in each particular channel. To save cost and footprint, electrical signals from the photodetectors are sometimes multiplexed in time using an electrical switch such as an analog CMOS switch that probes the signal from each photodetector one at a time.

A typical prior art circuitry for sequentially monitoring optical power in a plurality of optical channels is shown in FIG. 1. Eight photodetectors 10 in the form of PIN photodiodes (PD) are used to detect light of 8 optical channels schematically represented by broken arrows 5. Each of the photodetectors are followed by a trans-impedance amplifier (TIA) 15, for example formed by an operational amplifier 20 connected in parallel with a resistor “RF” and a capacitor “CF” forming a feedback RC circuit 25 as known in the art. The TIAs 15 convert photocurrents from the respective pin diodes 10 into voltage signals that are then provided to respective input terminals 31 of an analog switch 30. The analog switch 30 has a plurality of signal input terminals 31 and one signal output terminal 32, and is operable to connect any of the input terminals 31 to the output switch terminal 32, one at a time, so as to perform multiplexing of the voltage signals in time. The multiplexed voltage signal at the output switch terminal 32 is amplified by a post-amplifier 35, optionally filtered using a low-pass filter (LPF) to reduce noise, and sent to an analog-to-digital converter 40 before providing to a processor (not shown) for analysis.

The prior-art voltage multiplexing scheme shown in FIG. 1, although being capable of performing its intended functions, has also a number of drawbacks. Firstly, it requires a plurality of TIAs 15, one per PD 10. Each of the amplifiers 15 has to be extensively calibrated, and requires its own space on the printed circuit board (PCB). Furthermore, the material costs of the circuitry of FIG. 1 is high due the large number of TIAs, each requiring precision resistors RF for the trans-impedance (TZ) feedback circuits. Since each of the TIAs 15 has to be powered, the resulting circuit consumes a relatively large amount of electrical power.

An object of the present invention is to overcome the shortcomings of the prior art by providing a current multiplexing circuit that does not require a separate amplifier for each current signal and is compact.

Another object of the present invention it to provide an optical power monitor for sequentially monitoring a plurality of optical signals using a current multiplexing circuit that uses low electrical power, low chip count, is compact and easy to calibrate.

### SUMMARY OF THE INVENTION

In accordance with the invention, a current multiplexing circuit is provided comprising a plurality of input terminals for receiving a plurality of current signals, a multiplexing switch coupled to the plurality of input terminals for sequentially coupling each of the plurality of input terminals to an output switch terminal for transmitting one of the current signals at a time, an input switch for selectively coupling to the reference potential those of the plurality of the input terminals that are not coupled to the output switch terminal by the multiplexing switch, and an operational amplifier having a differential input coupled to the output switch terminal and to a reference potential, so as to amplify each of the electrical current signals in a selected sequence while maintaining the output switch terminal at substantially the reference potential.

In accordance with another aspect of this invention, a current monitor is provided comprising a current multiplexing circuit according to claim 2, and further comprising: an analog to digital converter (ADC) coupled to an output port of the operational amplifier for providing a digital signal in response to an analog electrical signal from the operational amplifier; and, a controller coupled to the ADC for receiving the digital signal and for providing an output signal indicative of each of the plurality of current signals transmitted by the multiplexing switch in the selected sequence, wherein the controller is programmed to generate control signals for controlling the multiplexing switch so as to connect one of the input terminals to the output switch port at a time, and for controlling the input switch so as to connect to the reference potential those of the input terminals that are not currently connected to the output switch terminal of the multiplexing switch.

Another aspect of the present invention relates to a method for monitoring a plurality of current signals using the current multiplexing circuit of the present invention, the method comprising the steps of: a) providing the plurality of current signals to the plurality of input terminals, b) recording a reference signal obtained from an output of the operational amplifier when the multiplexing and input switches are in a referencing mode of operation, c) operating the multiplexing and input switches to sequentially connect at least some of the input terminals to the output switch terminal, and d) calibrating a signal obtained from the output of the operational amplifier utilizing the reference signal to compensate for undesirable leakage currents and/or temperature variations.

### BRIEF DESCRIPTION OF THE DRAWINGS

The invention will be described in greater detail with reference to the accompanying drawings which represent preferred embodiments thereof and in which like reference labels are used to indicate like elements, wherein:

FIG. 1 is a diagram of a prior art optical power monitoring circuit with voltage signal multiplexing;

FIG. 2 is a diagram of a current multiplexing circuit according to the present invention;

FIG. 3 is a diagram of a trans-impedance amplifier used in the circuit of FIG. 2 having two SPDT switches for gain switching;

FIG. 4 is a diagram showing a of the current multiplexing circuit of FIG. 2 with an analog to digital converter for current monitoring;

FIG. 5 is a diagram showing pin connectors and control interfaces for a particular embodiment of the multiplexing and input switches used in the current multiplexing circuit shown in FIG. 2;

FIG. 6 is a schematic block diagram illustrating the controller used in the optical power monitor of the present invention;

FIG. 7 is a graph showing experimental error in optical power measurement using the current multiplexing circuit of the present invention without the auto-zeroing step;

FIG. 8 is a graph illustrating the reduction in optical power measurement error due to the use of the auto-zeroing step;

FIG. 9 is a diagram illustrating the use of a reference current source in the current multiplexing circuit of the present invention for output signal calibration;

FIG. 10 is an equivalent circuit of the current multiplexing circuit shown in FIG. 2.

FIG. 11 is a graph illustrating the power measurement error due to frequency-dependent crosstalk for different numbers of monitored photodetectors.

FIG. 12 is a diagram of the current multiplexing circuit for optical power monitoring combining reversed biased photodiodes and zero biased photodiodes;

FIG. 13 is a schematic block diagram of an optical power monitor for monitoring 64 optical signals.

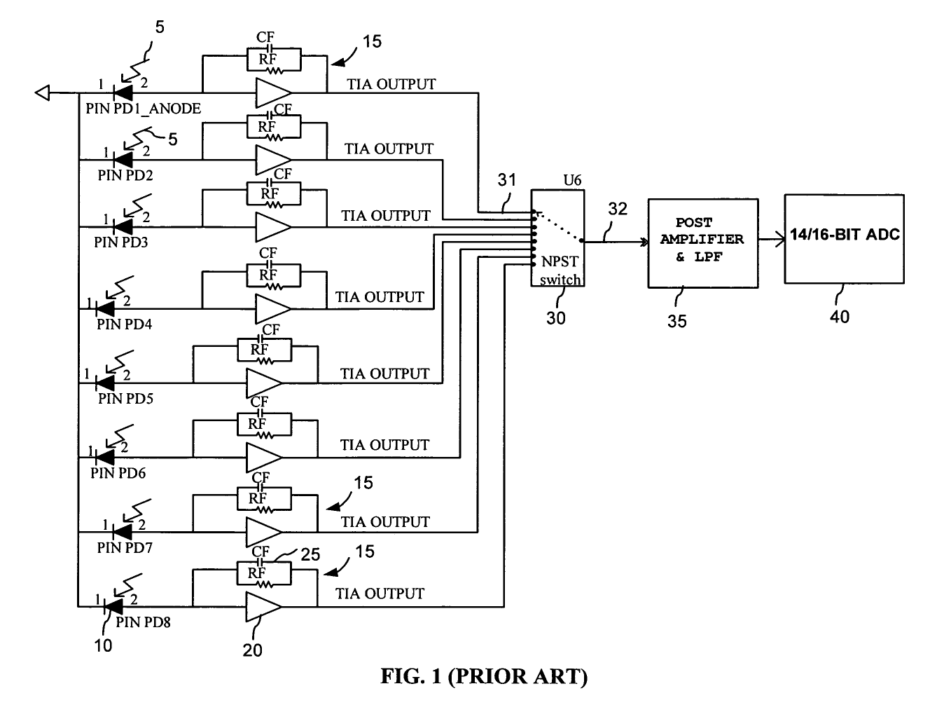

### DETAILED DESCRIPTION

The term “terminal” is used herein to mean a point of electrical connection, for example on a circuit board, including but not limited to leads, nodes, pins and other types of electrical connectors. A terminal used as an input or output of a device or a circuit board element is also referred to herein as “port”. The terms “current” and “potential” when used as nouns refer herein to electrical current and electrical potential, respectively.

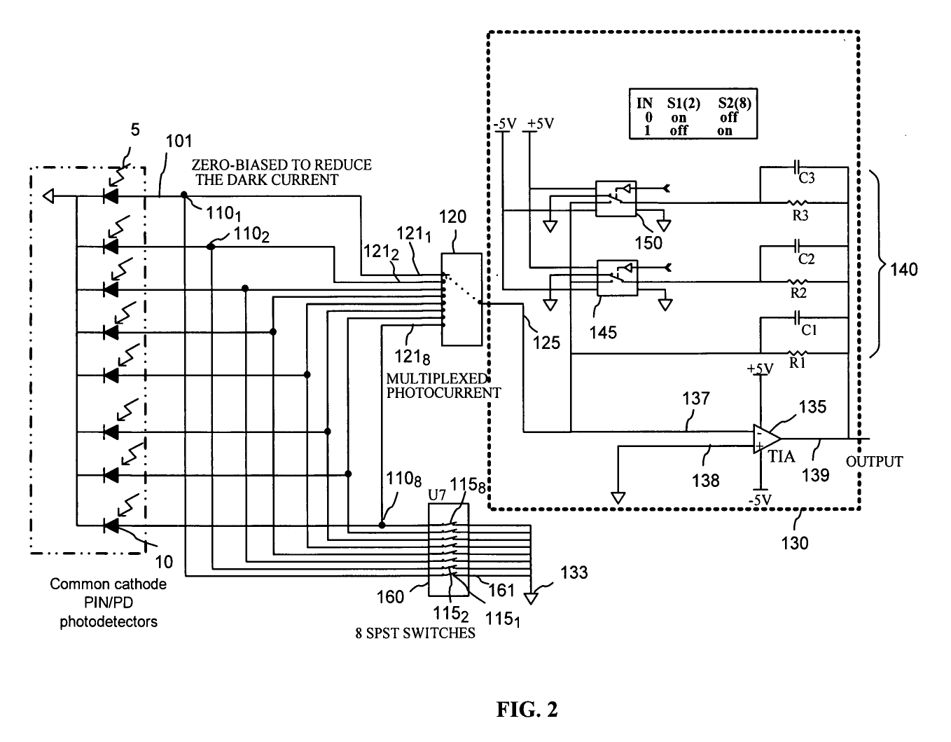

A preferred embodiment of a multiplexing circuit for multiplexing a plurality of current signals according to the present invention is shown in FIG. 2, wherein electrical connections between circuit elements are schematically shown by solid lines.

A plurality of input terminals 110₁ . . . 110_{N}, hereinafter generally referred to as input terminals 110, are provided for receiving a plurality of current signals in the form of electrical currents Iₙ, one current signal per input terminal, from a plurality of photodetectors (PD) 10, which in the context of this description can be generally considered as ideal current sources. Each of the input terminals 110 is connected to one of a plurality of analog input ports 121₁, . . . , 121_{N} of a multiplexing switch 120, which is preferably embodied as an analog NPST (N Poles Single Throw) CMOS switch having a digital control interface.

The multiplexing switch 120 will also be referred to herein as the NPST switch. In the shown embodiment N=8, so that the NPST switch 120 can also be referred to as the 8P1T switch or 8PST switch. In other embodiments the number of current signals to multiplex and, accordingly, the number N of input ports 121 of the NPST switch 120 can be either smaller or greater than 8, but at least 2. The output signal port 125 of the multiplexing switch 120 will also be referred to herein as the output switch terminal.

Responsive to a digital control signal, the multiplexing switch 120 can be switched to connect any one of the N analog input ports 121 to a single analog output port 125 for transmitting one of the current signals Iₙ at a time. In applications it is typically desired that when a selected current signal, for example I₁, is transmitted by the multiplexing switch 120, the other N−1 current signals I_{N-1}, . . . , I_{N} are substantially blocked by the switch 120, so that a current Iₒᵤₜ at the output switch terminal 125 is substantially equal to the current signal, in this example I₁, received at the selected input switch port, in this example 121₁. However, conventional solid-state analog switches such as CMOS switches are not ideal current blockers; in these switches small currents can be flowing, or ‘leaking’ between nominally disconnected input ports and output ports of the switch when there is a potential, i.e. voltage, difference therebetween. These leakage currents may be temperature dependent and, in the case of the multiplexing switch 120, result in an undesirable crosstalk between the input current signals Iₙ at the output of the switch, with the output current signal Iₒᵤₜ differing from the selected input current, in this example I₁, by a generally unknown value that can vary with temperature. The present invention provides means to substantially reduce and calibrate out the magnitude and temperature dependence of these leakage currents, and the associated crosstalk.

For this purpose, an input switch 160 is connected between the input terminals 110 and a source of a reference potential, for example ground. As shown in FIG. 2 by way of example, the input switch 160 can be embodied as a bank of N independently switchable analog SPST (single pole single throw) switches preferably having a common control interface, with output signal ports 161 connected to ground 133. The input switch 160, which in this embodiment will also be referred to as the N-SPST switch or as 8-SPST switch, is operable to couple any selected group of the input terminals 110 and, therefore, corresponding input signal ports 121 of the NPST switch 120, to the reference potential, or ground.

The output switch terminal 125 of the multiplexing switch 120 is connected to a single-ended input terminal 137 of a differential input of an operational amplifier (OA) 135, with the other single-ended input port 138 thereof coupled to the same reference potential as the output port of the input switch 160, as shown in FIG. 2—to the ground. A feedback circuit 140 is connected between an output terminal 139 of the OA 135 and its inverting input 137 for providing a desired trans-impedance (TZ) therebetween, so as to form a trans-impedance amplifier (TIA) 130 from the OA 135. In the shown embodiment the feedback circuit 140 includes two SPDT (single pole double throw) switches 145, 150 connected in parallel for adding additional TZ resistors R2 and/or R3 to a base TZ resistor R1. The SPDT switches 145, 150 provide for a selectable TZ of the TIA 130, which is advantageous for increasing the dynamic range in current measurement applications. Other embodiments may have a different number of SPDT switches in the feedback circuit of the TIA 130, or may have no SPDT switches if a particular application does not require TIA gain switching.

Importantly, the coupling of the second, for example—non-inverting input terminal 138 to the reference potential leads to a potential at the output switch terminal 125 being also nearly equal to the reference potential, i.e. that of the ground in the shown embodiment, due to a well-known property of operational amplifiers that tend to equalize potentials on the inverting and non-inverting inputs thereof. Preferably, the OA 135 and other relevant circuit elements are selected so that the potential difference between the output switch terminal 125 and the reference potential, i.e. ground, is no more than 10 mV (millivolt), and is preferably less than 5 mV; a suitable selection of circuit elements for a particular application will be known to those skilled in the art.

Advantageously, this arrangement enables to maintain a substantially zero, for example less than 10 mV and preferably less than 5 mV, potential difference across the NPST switch 120 between the output switch terminal 125 and those of the input signal ports 121 which are coupled to the ground by the input switch 160, provided that the input switch 160 has a low ON resistance as described herein below. The near-zero voltage across the switch 120 serves to minimize leakage currents and photocurrent crosstalk in the multiplying switch 120, and to substantially reduce detrimental variations of the leakage current due to variations in operating temperature of the circuit; this is especially advantageous for applications wherein the multiplexing circuit of the present invention is used for accurate absolute or relative measurements of current signals, such as in monitoring weak optical signals.

Similarly, the use of the SPDT switches 145, 150 rather than SPST switches in the TIA feedback circuit 140 advantageously enables to minimize both the magnitude and the temperature variation of leakage currents associated with these switches, i.e. currents flowing through the switches when they are switched to break a respective TZ sub-circuit of the TIA 130.

The NPST switch 120, the N-SPST switch 160 and the SPDT switches 145 and 150 used in the current invention should have very low, less than 10 Ohm and preferably less than 3 Ohms, ‘ON’ resistance, to ensure that the near-zero potential difference across the switch is maintained during operation. The ‘ON’ resistance of a switch is understood herein as the resistance between an input port and an output port of the switch when said ports are connected by the switch. Low-resistance digitally controlled analog switches of a variety of switching configurations are currently commercially available from a variety of suppliers in the form of CMOS integrated circuits (IC) with bias voltages of 5 Volts or less and switching times less than 100 ns. Such low-resistance analog CMOS switches provide considerable advantages for the current invention compared to previous generations of CMOS switches having ‘ON’ resistance of the order of 80-150 ohms. Indeed, using a high-resistance switch as the multiplexing switch 120 would be detrimental for the circuit operation as it would substantially increase the risk of forward biasing of the PDs 10 when their output is read, leading to an increase in the PD dark current and a non-linearity of the light-current characteristics I(P). The input switch 160 should have an ‘ON’ resistance less than 10 Ohms and preferably less than about 3 Ohms for the grounding of the input ports 121 of the multiplexing switch 120 to be effective, so as to maintain the potential difference across the multiplexing switch 120 at a near-zero voltage as described hereinabove.

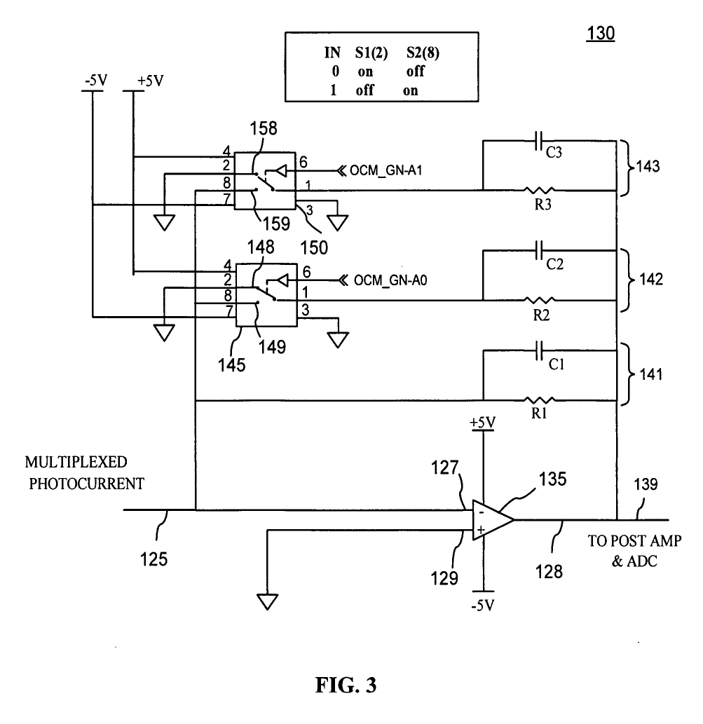

The SPDT switches 145, 150 should preferably have a low ‘ON’ resistance to ensure that a near-zero voltage across these switches is maintained and current leakage through this switches is suitably low and substantially temperature independent. Possible functional schemes of the SPDT switches 145, 150 embodied as digitally-controlled analog CMOS switches are more clearly shown in FIG. 3, which gives a zoomed-in view of the electrical scheme of the TIA 130 shown in FIG. 2. The shown exemplary functional schemes and pin layouts of the SPDT switches 145, 150 correspond to monolithic analog CMOS SPDT switches ADG619BRT manufactured by Analog Devices Inc, which have a suitably low ‘ON’ resistance less than about 6 Ohm, and typically about 4 Ohm.

A digital control signal applied to a pin ‘6’ can switch each of the SPDT switches 145, 150 so as to either make an electrical connection between an associated TZ sub-circuit 142 or 143 and the input port of the OA 135 by connecting to a pole 159 or 149, thereby adding an associated TZ resistor R2 or R3 in parallel to the base resistor R1, or to break that connection by switching the associated TZ sub-circuit 142 or 143 to ground by connecting to a pole 158 or 148; the former of these two switching states will be referred to herein as the ‘ON’ state of the respective SPDT switch, with the later referred to as the ‘OFF’ state of the SPDT switch. In either of these two switching states, the electrical potential difference across each of the SPDT switches 145 and 140 is maintained close to zero, for example less than 5 mV, thanks to the low ‘ON’ resistance of the SPDT switches, thereby substantially reducing the associated leakage currents.

By choosing precision TZ resistors R1, R2 and R3 with low temperature coefficient, for example ≦25 ppm/° C., they don't have to be calibrated with respect to temperature. By way of example, the resistor values can be selected as follows: R1=3 MΩ, R1=100 KΩ, and R3=10 KΩ, so that the TIA 130 gain can be switched from a maximum gain when the DPST switches 145 and 150 are both turned OFF, to an intermediate gain when only the DPST switches 145 is ON and the DPST switches 150 is OFF, and to a small gain when the DPST switches 150 is ON. The OA 135 is preferably a low-noise-cum-precision linear or logarithmic operational amplifier.

The present invention thus advantageously provides a current multiplexing circuit which utilizes low resistance analog switches that are substantially zero-biased so as to reduce both the magnitude and the temperature dependence of leakage currents normally associated with such switches.

Another advantage of the current multiplexing circuit of the present invention is that it enables simple calibration procedures for measuring the contribution of leakage currents in the switches and TIA voltage offsets to a signal at the output 139 of the TIA 130. Although small, this contribution may be detrimental in current measurement applications, and has to be accounted for to obtain reliable current readings. Advantageously, the combination of the multiplexing switch 120 and the input switch 160 can operate as a global optical shutter, substantially blocking current signals generated by the PDs 10 from reaching the output switch terminal 125. As described hereinafter, this functionality enables the current multiplexing circuit of the present invention to perform auto-calibration before and during normal operation of the circuit, wherein the contribution of the leakage currents and offset voltages to the output signal of the TIA 130 is evaluated and accounted for to obtain a corrected reading of the input current signals Iₙ from the voltage signal at the TIA output 139.

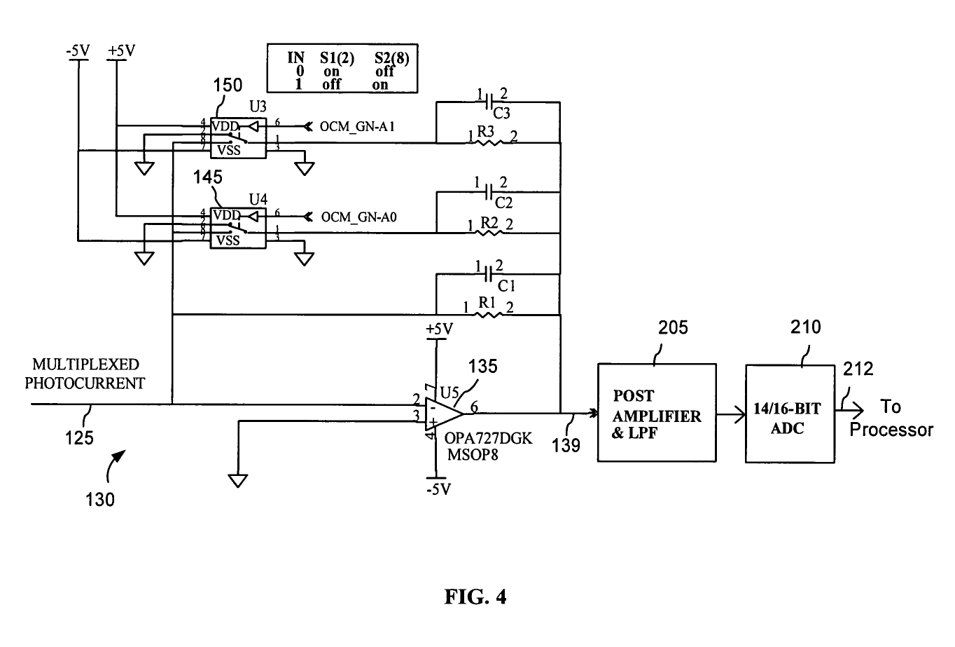

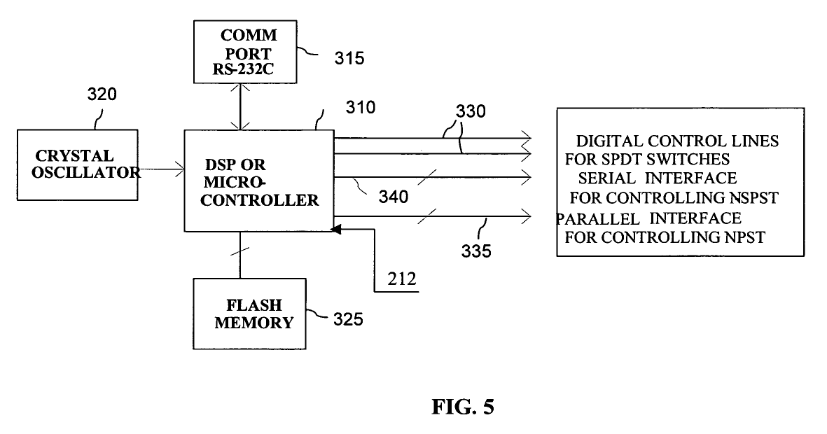

Operation of the current multiplexing circuit shown in FIG. 2 will be described hereinbelow with reference to an optical power monitor which utilizes said circuit for monitoring of optical power of a plurality of optical signals. In addition to the current multiplexing circuit shown in FIG. 2, the optical power monitor described herein also includes an analog-to-digital converter (ADC) 210 shown in FIG. 4 that is connected for converting the output voltage signal generated by the TIA 130 into a digital signal, and a controller 310 shown in FIG. 5. An optional post-amplifier 205 may be connected between the ADC 210 and the TIA 130, and may include a low-pass filter (LPF) for noise reduction. The controller 310 includes internal or external memory 325, and can be embodied using a digital signal processor (DSP), a microcontroller, an FPGA, a general purpose microprocessor such as those used in a computer, a stand-alone computer, or any suitable combination thereof as appropriate for particular application requirements. The digital signal at the output of the ADC 210, also referred to herein as the ADC count, is read by the controller 310 via a digital communication link 212. Digital control links 330, 340 and 345 are provided between the controller 310 and the switches 145, 150, 160 and 120, and the controller 310 is programmed for controlling said switches as described hereinbelow, and to read and process digital output of the ADC 210 to obtain information about optical powers received by each of the PDs 10. A serial communication port RS-232C is provided for reporting the optical power and/or photocurrent information obtained by the controller 310 as required. Depending on a particular embodiment of the NPST and N-SPST switches 120, 160, they can be furnished with either a parallel or a serial bus interfaces. As shown in FIG. 5 by way of example, the controller 310 uses a serial bus interface to control the input N-SPST switch 60, and a parallel bus interface to control the multiplexing NPST switch 120.

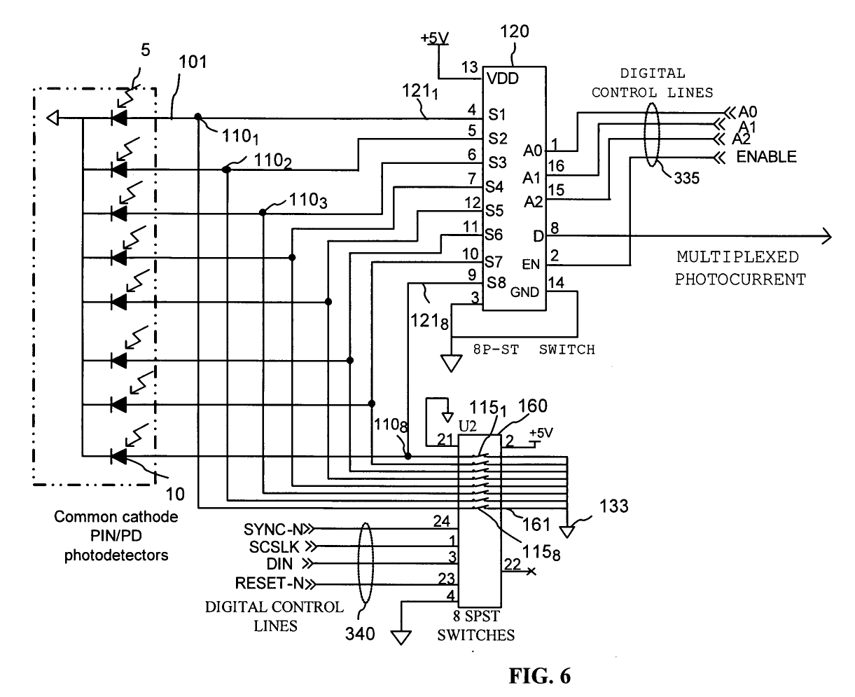

FIG. 6 shows exemplary functional schemes and pin layouts of the multiplexing switch 120 and the input switch 160 embodied, respectively, as analog CMOS switches ADG608 (8PST) and ADG714 (8SPST), respectively, produced by Analog Devices Inc. In the shown exemplary embodiment, analog input ports 121 of the 8PST switch 120 correspond to pins ‘4’ to ‘7’ and ‘9’ to ‘12’, while the output port of the 8PST corresponds to pin ‘8’. Pins ‘1’, ‘2’, ‘15’ and ‘16’ form a parallel control interface of the switch 120, wherein control signals from the controller 310 are received via the communication link 335 such as a parallel. Pins ‘1’, ‘3’, ‘23’ and ‘24’ of the exemplary 8-SPST switch 160 form a serial digital control interface thereof for receiving control signals from the controller 310 via a serial peripheral bus 340, with pins from ‘5’ to ‘20’ used pair-wise as input-output analog signal ports of the 8 SPST switches 115 of the input switch 160.

In operation, the photodetectors (PD) 10, which are labeled in FIG. 2 using alphanumeric labels from ‘PD1’ to ‘PD8’ and can be for example PIN or P/N photodiodes, generate current signals in the form of photocurrents Iₙ, n=1, . . . , N. These photocurrents are indicative of optical power received by each of the PDs 10, and are generally proportional thereto within a certain optical power range:

Iₙ=ηPₙ+I_{dark,} (1)

where I_{dark} is the PD dark current, and η is the PDs photosensitivity coefficient. As shown in FIG. 2, the PDs 10 are substantially zero-biased to ensure that the dark current I_{dark} is small, for example less than 50 pA, and the linear equation (1) holds in a wide range of optical powers.

According to one embodiment of the invention, the optical power monitor switches between two different modes of operation—a power monitoring mode and an auto-calibration mode, wherein the switches 120 and 160 are controlled in two different ways.

### Auto-Calibration

In this mode of operation, which is also referred to hereinafter as the referencing mode, the controller 310 generates a control signal to switch ON all 8 SPST switches 115₁ to 115₈ of the input switch 160 so as to connect output ports 101 of the PDs 10 to the ground 133, which ensures near zero voltage to all N=8 input ports 121 of the NPST switch 120. Simultaneously the NPST switch 120 is disabled, whereby all the input signal ports 121 are disconnected from the output switch terminal 125 so as to prevent photocurrents Iₙ from reaching the TIA 130. In this state, the input switch 160 and the multiplexing switch 120 together operate as a global optical shutter. By way of example, the 8PST switch 120 as shown in FIG. 6 can be disabled by a assigning a logic ‘0’ to a digital control signal “ENABLE” that is applied to pin ‘2’ by the controller 310.

The output of the TIA 130 is first optionally amplified by the post-amplifier 205, and then provided to the ADC 210. The controller 310 reads a reference signal in the form of an ADC count value L, which is also referred to herein as an ADC offset count or offset value, and stores it in the memory. The offset count is used for circuit calibration in the monitoring mode and accounts for leakage currents in the NSPT and DSPT switches and offset voltages. This process can be referred to as “auto-zeroing”.

Since the current at the input port of the OA 135 under these circumstances is mainly due to the current leakage in the NPST switch 120 and the TIA SPDT switches 145, 150 and can therefore be rather small, for example about 1 nA (nanoAmpere) or less, the TIA 130 may have to be set to a high-TZ high-gain state to provide an appreciable output voltage for the overall current leakage, for example by switching both SPDT switches 145 and 150 OFF so that the lower TZ resistors R2 and R3 do not shunt the large TZ resistor R1. In some embodiments the TIA 130 is sequentially switched to all possible gain states, and respective ADC offset count values are stored in the controller memory as illustrated in Table 1. For the given example, a leakage current of 1 nA will yield a voltage signal at the TIA output of about 3 mV, 0.1 mV and 10 μV when the TZ of the TIA 130 TZ is set to R1=3 MΩ, R2=100 KΩ, and R3=10 KΩ, respectively. To ensure a positive voltage at the input of the ADC 210, a small positive voltage, for example 2 mV, can be summed to the output of the TIA 130.

The capacitors C1, C2 and C3 in the feedback circuit of the TIA 130 can be selected so as to provide a suitably low bandwidth, for example about 100 Hz or less; the offset count can then be read without much noise at the input of the ADC 210. The controller 310 can optionally perform low pass filtering by numerical averaging to improve the noise performance.

### Monitoring Mode

In the monitoring mode, the controller 310 controls the multiplexing switch 120 and the input switch 160 in such a way so as to sequentially connect one of the input terminals 121 at a time to the output switch port 125 in a pre-determined sequence, while simultaneously connecting all other input terminals 121 to the ground.

For example, the multiplexing switch 120 is first switched by a control signal from the controller 310 to connect the input port 121₁ to the output switch port 125; simultaneously, the controller 310 sends a control signal to switch ON the SPST switches 115₂ to 115₈ so as to couple (N−1)=7 input ports 121₂ to 121₈ of the switch 120 to the ground, and to switch ‘OFF’ the SPST switch 115₁, thereby isolating the input ports 121₁ from the ground. The photocurrent I₁ is summed at the output switch port 125 with a small leakage current, and provided to the input of the TIA 130, which in response generates a voltage signal. The controller 310 obtains an ADC count reading M₁, subtracts from it the stored ADC offset value L, and determines therefrom the photocurrent I₁ and/or a respective optical power received by the PD1. This can be done, for example, using the following formulas:

I₁=[{M₁−L}/R]×[V_{REF}/G×2^{K}}, (2)

P₁=R_{λ}×I₁ (3)

where R is the TZ value of the TIA 130, which is approximately equal to one of R1, R2 or R3 values, depending on the states of the SPDT switches 145, 150 of the TIA 130, K is the ADC's resolution. Parameter G is the voltage gain of the post-amplifier 205. Parameter K is the resolution of the ADC 210, and can be for example 14 or 16. V_{REF} is an ADC reference voltage fed to the ADC; V_{REF} can be from 2.5V to 5V. R_{λ}=1/η is the responsivity of the PD1; typical R_{λ} for InGaAs PIN PDs are ˜1 mW/mA at 1550 nm. These parameters are assumed to be know, and can be stored in the controller's memory.

After a selected dwell time T, which can be as small as 100 μs or less, the multiplexing switch 120 is switched to connect a next of the input ports of the NPST switch 120, for example the port 121₂, to the output switch terminal 125; simultaneously, the controller 310 generates a control signal to switch ‘ON’ the SPST switch 115₁, and to switch “OFF” the SPST switch 115₂, while keeping the rest of the SPST switches to 115₃ to 115₈ ‘ON’ for grounding of the respective NPST input ports. In this state the current at the input of the TIA 130 is approximately equal to the photocurrent I₂; the controller 310 obtains a corresponding ADC count reading M₂, from which it subtracts the stored offset value L to determine the photocurrent I₂ and/or a respective optical power received by the PD2. This switch sequence is continued until each of the N photocurrents Iₙ is passed to the input of the TIA 130 one by one, and optical powers received by each of the PDs 10 are estimated by the controller 310.

Accordingly, during the monitoring mode of operation the multiplexing switch 120 performs time-domain multiplexing of the current signals generated by the PDs 10; it provides to the TIA 130 a multiplexed current signal Iₒᵤₜ, which at any given time is substantially equal to one of the photocurrents Iₙ plus the small leakage currents leaking through the nominally open terminals of the NSPT and DSPT switches 120, 145 and 150. The controller 310 reads a signal obtained from the output of the operational amplifier 135 via the ADC 210, and calibrates it utilizing the reference signal, i.e. the stored offset value, to compensate for undesirable leakage currents and/or temperature variations.

Since high optical power can result in a voltage signal that saturates the ADC 210, the gain, or TZ of the TIA 130 may have to be switched using the SPDT switches 145 and 150 as described hereinabove, and the resulting ADC reading stored. Therefore in some embodiments the offset ADC count value L and the ADC count value M in monitoring mode are read and stored for two or more TZ values of the TIA 130, as illustrated in Table 1 for PD1 related ADC readings. The current I₁ is then computed using equation (2) with values L and M selected from a column of Table 1 corresponding to a TZ of the TIA 130 that does not lead to a saturation of the ADC 210. For example, if it is found that switching the TZ of TIA 130 to R1 by turning both SPDT switches OFF in monitoring mode saturates the ADC 210 when the PD1 is connected to the TIA 130, but switching the TZ of the TIA 130 to R2 does not saturate the ADC 210, the photocurrent is computed using the equation

I₁=[{M2−L2}/R]×[V_{REF}/G×2^{K}}. (4)

TABLE 1
ADC count readings used for PD1 monitoring

| NSPT switch | ADC count | ADC count | ADC count |
|---|---|---|---|
| state | TZ = R1 | TZ = R2 | TZ = R3 |
| Disabled | L1 | L2 | L3 |
| Enabled, PD1 | M1 | M2 | M3 |
| terminal | | | |
| connected to | | | |
| TIA | | | |

The aforedescribed method of operation of the current multiplexing circuit of the present invention for monitoring of a plurality of photocurrents involves calibration of a single TIA and is advantageously simple and operationally efficient. Generally, it involves the following main steps:

a) providing the plurality of photocurrent signals Iₙ to the plurality of input terminals 110 coupled to the multiplexing switch 120 having the output switch terminal 125 coupled to the reference potential, for example ground;

b) recording a reference signal obtained from an output of the operational amplifier 135 when the multiplexing and input switches 120, 160 are in a referencing mode of operation;

c) operating the multiplexing and input switches 120, 160 to sequentially connect at least some of the input terminals to the output switch terminal 125 while connecting the rest of the input terminals to the reference potential, such as ground, for maintaining a substantial zero voltage across the multiplexing switch 120;

d) calibrating a signal obtained from the output of the operational amplifier 135 with the reference signal to compensate for undesirable leakage currents and obtain a current or optical power measurement signal; and,

e) repeating steps (b)-(d) at selected time intervals for dynamically adjusting the calibrating to ambient temperature variations.

The auto-calibration procedure can be performed periodically during normal operation of the device, for example every few minutes or as required by operation conditions, so as to update the offset values stored in the controller's memory and account for possible changes in the leakage currents due to changes in circuit temperature and component aging. The method therefore enables accurate current and optical power measurements in a wide dynamic range of input currents and optical signals with dynamic offset compensation in varying operating conditions.

By way of example, the exemplary circuit configuration of the current multiplexing circuit as shown in FIGS. 2 and 6 can be used to monitor optical powers between 0 dBm and −65 dBm, and can work with a variety of commercially available photodetectors including but not limited to Silicon and InGaAs based photodetectors operating in a wide spectral range from 400 nm to 1700 nm. For numerical examples described herein, the PDs 10 are InGaAs PIN diodes EPM-605 fabricated by JDSU. A wider dynamic range can be obtain, for example by using a TIA with a wider range of switchable gains, which may involve using a larger number of SPDT switches in the feedback circuit of the TIA 130.

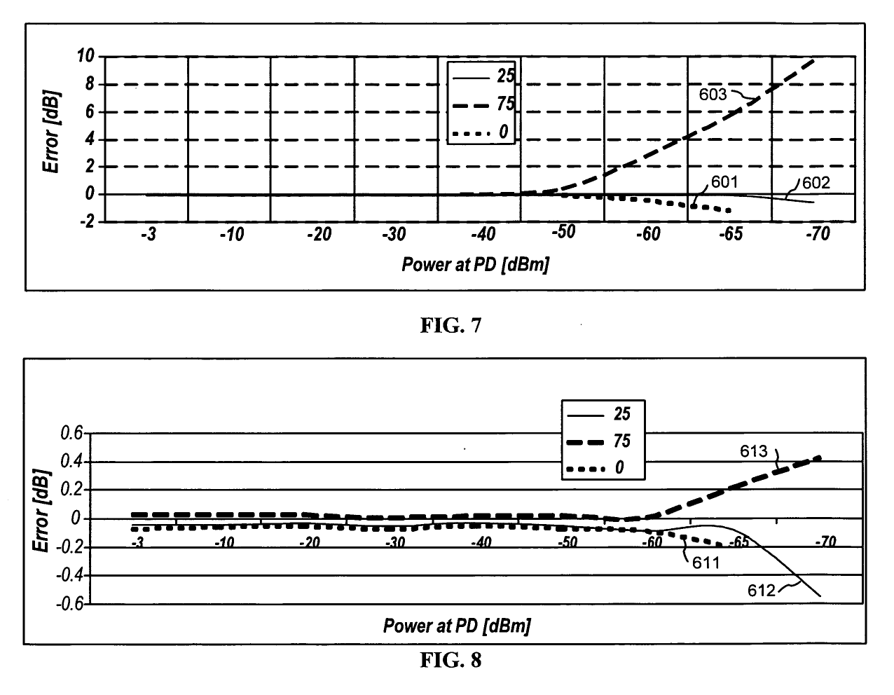

FIGS. 7 and 8 show experimental curves illustrating the improvement in optical power measurement accuracy that is enabled by using the current multiplexing circuit of the present invention as shown in FIGS. 2-5 and the auto-zeroing approach of the present invention. FIG. 7 shows the experimental error when measuring optical power from −3 to −70 dBm when the auto-zeroing function is disabled. Curves 601, 602 and 603 correspond to measurements taken at 0, 25 and 75 degrees C., respectively. The experiment was performed using an NPST switch with N=32. Large errors at 75 C and power level below −50 dBm are due to leakage currents in the NPST and SPDT switches.

Curves 611, 612 and 613 in FIG. 8 show the power measurement error experimentally obtained under the same conditions as the curves 601, 602 and 603, but using the auto-zeroing function as described hereinabove. As clearly seen, the auto-zeroing function substantially reduces the power measurement error, which now stays within +\−0.5 dB over the whole temperature range from 0 C to 75 C even for a received optical power as low as −70 dBm.

### Alternative Calibration Method

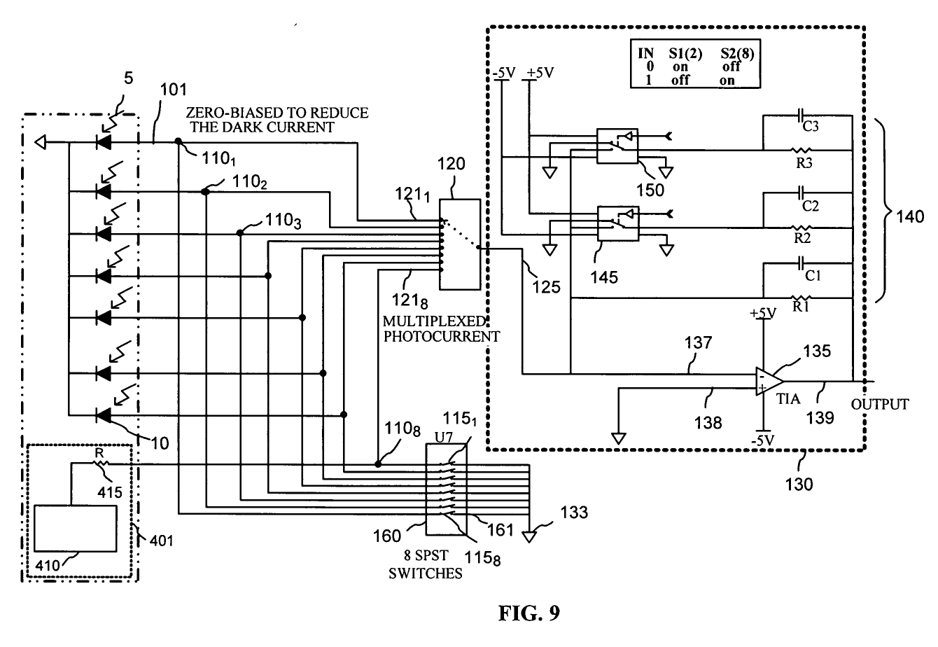

The aforedescribed auto-zeroing process represents one possible approach to calibrating the current multiplexing circuit of the present invention, with other approaches possible within the scope of this invention. With reference to FIG. 9, one such alternative approach may include connecting a stable source 401 of a known reference current I_{ref} to one of the input terminals 110, and using this source to calibrate the output signal of the current multiplexing circuit in the monitoring mode of operation. The reference current source 401 can be implemented in a variety of ways as would be known to those skilled in the art; as shown in FIG. 9, it includes a stable voltage source 410 and a temperature stable resistor 415.

In this embodiment, the auto-calibration procedure may include the following steps: i) receiving the known reference current I_{ref} in one of the input terminals, for example terminal 1108 as shown in FIG. 9; ii) connecting said one of the input terminals 1108 to the output switch terminal 125 using the multiplexing switch 120; and, iii) using the input switch 160, connecting the rest of the input terminals, i.e. the terminals 110₁ to 110₇ receiving the photocurrent signals for monitoring, to the source of the reference potential, preferably the ground. A reference signal that is obtained at this stage by the controller 310 in the form of an ADC count read L′ is stored in the controller's memory and is subsequently used as the ADC count offset when processing signals obtained when monitoring PD 10 photocurrents.

Advantageously, this embodiment of the method does not require a separate “auto-zeroing” step when the multiplexing switch 120 is disabled, since the reference signal used in calibration is simply a signal that is recorded when the multiplexing switch 120, while stepping through different input ports as during the monitoring mode of operation described hereinabove, connects to the input terminal receiving the reference current signal I_{ref}.

By way of example, calibrating of the ADC count M1 that is read by the controller 310 when measuring the PD1-related signal can be performed in this case according to the following equation (4):

I_{I}=I_{ref}+[{M₁−L′}/R]×[V_{REF}/G×2^{K}}, (5)

which is now used in place of equation (2) of the first embodiment of the method.

A possible drawback of this approach is that it requires the reference current source 401 and can monitor one optical signal less than the first embodiment using the auto-zeroing step.

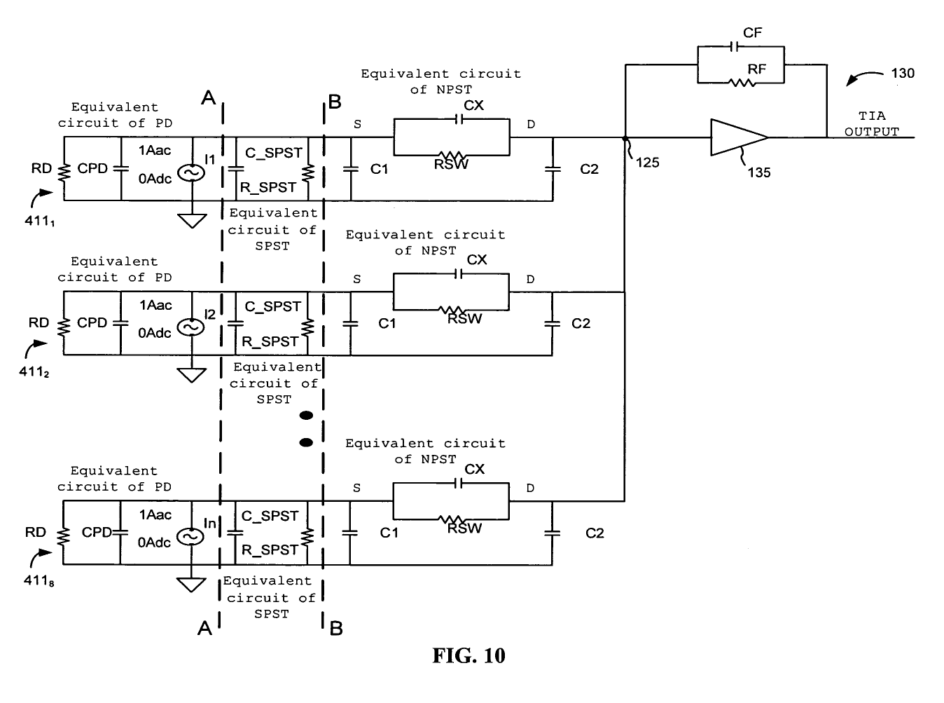

One potential problem that may arise when multiplexing photocurrents from a plurality of photodiodes using a single analog CMOS switch is a frequency-dependent crosstalk. This crosstalk can be understood by referring to FIG. 10, which shows an equivalent electrical circuit of a current multiplexing circuit similar to that shown in FIGS. 2 and 6, but for a general case of N photodiodes.

From left to right, the equivalent circuit shown in FIG. 10 is composed of equivalent circuits of the array of photodetectors 10 shown to the left of a dashed line ‘AA’, an equivalent circuit of the analog CMOS NPST switch 120 shown to the right of a dashed line ‘BB’, and an equivalent circuit of the input N-SPST switch 160 shown therebetween. From top to bottom, the overall equivalent circuit shown in FIG. 10 has N electrical channels 411₁-411_{N}. One for each photodetector, all commonly connected at the output switch port 125 at the input of the OA 135.

In FIG. 10, conventional circuit notations are used to represented equivalent resistances and capacitances of the photodetectors 10 and switches 102 and 160. Equivalent resistance RD and capacitance CPD of the photodetectors are typically tens of Mega Ohms and 1 or 2 pF, respectively. An equivalent resistance R_SPST of each of the SPST switches 115 of the input N-SPST switch 160 is typically under 2 ohms for ON condition, and can be approximately considered as infinitely large for the OFF condition of the respective SPST switch. An equivalent capacitance C_SPST of the SPST switch is typically about 17 pF. RSW represents the low-frequency resistance between an input and output ports of the NSPT switch 120, and is typically under 5 Ohms in ON condition. Equivalent input and output capacitances of each channel of the NPST switch C1 and C2 are typically about 15 pF each.

CX is an input-output capacitance of the NPST switch 120 in the OFF state, and is typically about or below 1 pF; in combination with a finite, although small, resistance R-SPST of the SPST switches in ON condition, this capacitance provides a main contribution to the cross-talk at high frequencies. The finite ON resistance of the SPST switch creates a small voltage drop, for example about 2 mV when a 1 mA current flows through a 2 Ohm R-SPST ON resistance, which acts as a Thevenin voltage source that drives an alternating current through the multiplexing switch 120. The problem becomes more compounded if more PDs are multiplexed.

A noise gain at the output of the TIA 130 depends on a total shunt capacitance CD at the input of the TIA 130, and increases when CD increases. Regardless which of the photodetector 10, if any, is selected by the multiplexing switch 120 for connecting to the TIA 130, each photodetector 10 contributes into this shunt capacitance, which can be estimated as CD=N×C2+C1+C_SPST+CPD. For example, if N=16, i.e. a 16×1 multiplexing switch is used to switch between 16 photodetectors, the shunt capacitance CD, which appears at the inverting input of the TIA 130, can be around 180-200 pF. Such a large shunt capacitance may considerably increase the noise gain of the TIA 130, and leads to an error in determining the received optical power.

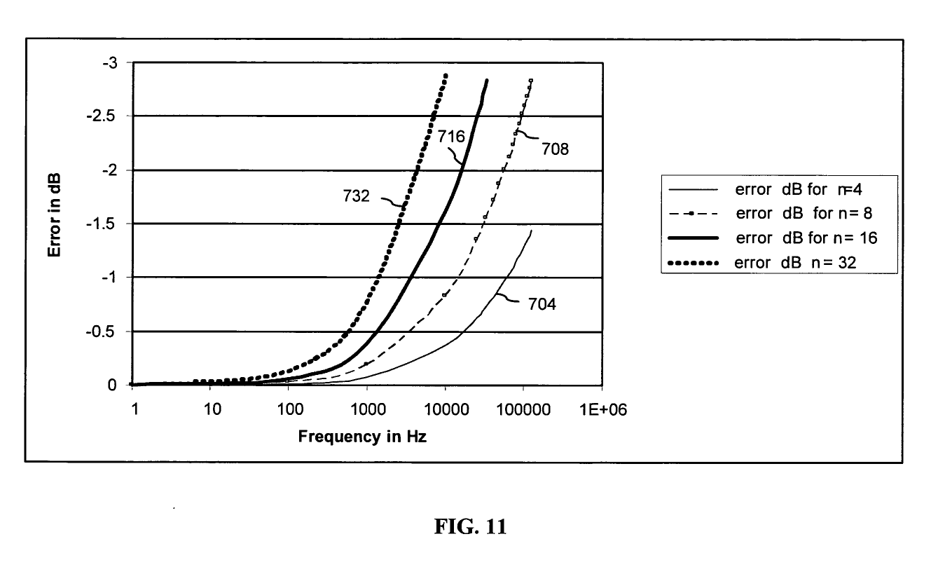

FIG. 11 shows simulation results illustrating frequency characteristics of the power measurement error induced by the frequency-dependent crosstalk when the number N of photocurrents being multiplexed is 4, 8, 16 and 32. The simulations were performed for measuring a −60 dBm optical signal generating a 1 nA photocurrent, when the photocurrent generated by the other (N−1) photodiodes are much stronger, 1 mA each. As seen from the figure, this crosstalk may result in inaccurate measurements when monitoring a large number of photodiodes at frequencies above about 1 kHz. This frequency-dependent crosstalk can be reduced by selecting the input switch 160 having a very low ON resistance, for example less than 1 Ohm, by selecting the multiplexing switch 120 having a very low OFF capacitance CX, for example less than 1 pF, and by decreasing the frequency bandwidth of the TIA 130 and the post-amplifier 205. The measurement error associated with the frequency-dependent crosstalk can also be reduced by using digital signal averaging at the controller 310.

In the aforedescribed embodiments the PDs 10 are substantially zero biased, with their cathodes commonly grounded, and their anodes coupled to the virtual ground via the NPST switch 120 and the OA 135. The zero-biased configuration leads to small dark currents I_{dark}, and a wide range of optical powers, for example 60 dB or more, of approximately linear Pₙ(iₙ) characteristics as described by equation (1). Although advantageous for detecting small to moderate optical powers, for example from −70 to 0 dBm for a typical InGaAs-based PIN photodiode, other embodiment may have photodetectors that are reversed biased.

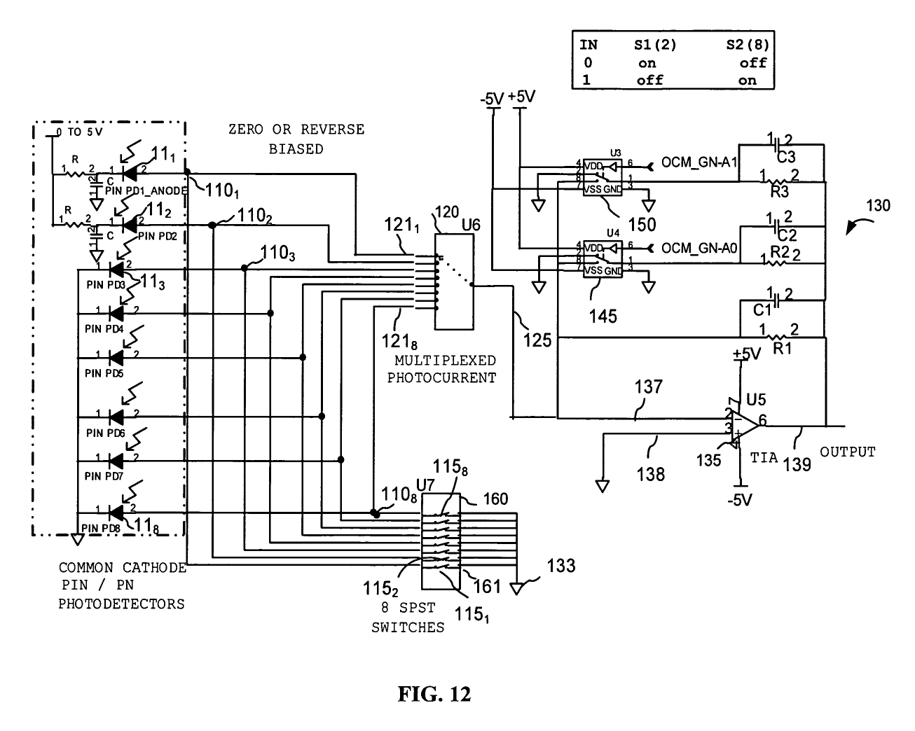

FIG. 12 illustrates by way of example an embodiment of the current multiplexing circuit of the present invention, wherein two out of 8 photodetectors 11₁ to 11₈, namely the photodetectors 11₁ and 11₂, are reversed biased. Operating the photodiodes under a reverse bias typically increases the dark current and makes it more sensitive to temperature, thereby reducing the dynamic range of the optical power measurements. The reversed biased configuration can however be useful in some application, such as when there is a need for measuring more than 1 mA photocurrent from a photodetector having a small photosensitive area, for example less than about 75 μm in diameter.

The aforedescribed current multiplexing scheme of the present invention, wherein a plurality of current signals is directly multiplexed using a low-resistance analog multiplexing switch prior to being converted to voltage signals, and the optical power monitor based thereupon, have considerable advantages compared to the prior art approach based on multiplexing of voltage signals. Detrimental effects of the crosstalk and current leakages, which had previously precluded the direct current multiplexing using analog solid-state swatches in the prior-art devices, are successfully mitigated by the present invention. The optical power monitor of the present invention uses less hardware, consumes less power in operation, and enables a simple calibration procedure that can be performed dynamically during normal operation of the device. The current multiplexing scheme of the present invention can be used for direct multiplexing of current signals from current sources other than photodetectors.

As we confirmed experimentally, at least 16 photocurrents from an array of 16 photodiodes can be successfully multiplexed and monitored as described hereinabove using a single 16PST CMOS switch and a single TIA, with a high power measurement accuracy within wide temperature and optical power ranges. Direct multiplexing of a larger number of photocurrents with a single multiplexing switch could be performed according to the present invention, for example at lower operation frequencies, subject to the availability of multiplexing switches with a large number of input ports.

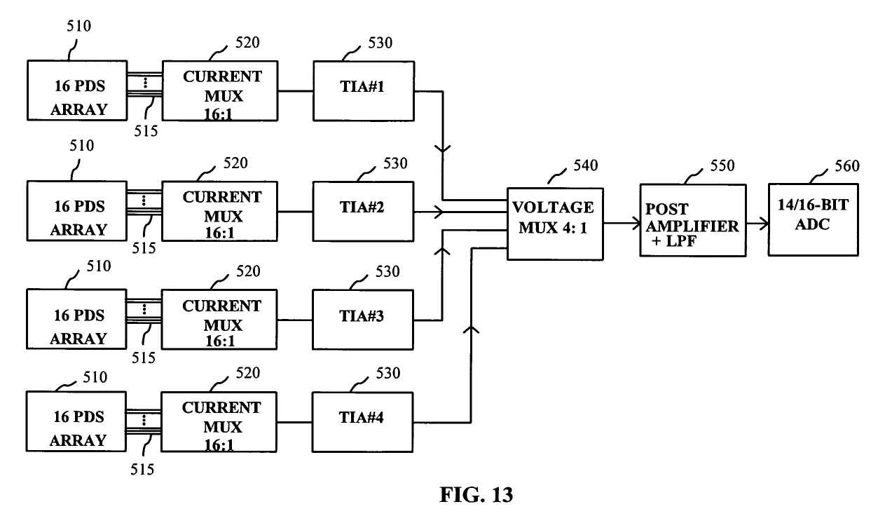

An alternative approach to monitoring a very large number of PDs is to group them in smaller blocks using one TIA per block of PDs. This approach is illustrated in FIG. 13, showing a schematic block diagram of an optical power monitor according to an embodiment of the present invention, for monitoring optical power that is incident on as many as 64 PDs. The PDs are grouped in four PD arrays 510, each including 16 PDs that can be commonly connected in the zero biased configurations as shown in FIG. 2. Photocurrents 515 from each PD array 510 are multiplexed using a dedicated analog 16SPT switch 520, and a multiplexed current signal from each of the switches 520 are separately converted to voltage signals by four TIAs 530. The voltage signals from the TIAs 530 are then multiplexed by a 4:1 voltage multiplexer 540 as known in the art, and the multiplexed voltage signal is provided through a post-amplifier 550 to an ADC 560 for converting into a digital signal which is then provided to a controller. Advantageously, only four TIAs are required and need to be calibrated in this embodiment, rather than 64 TIAs that would have to be used and calibrated in the prior-art approach. A preferred embodiment of such a monitor includes also 4 input 16-SPST switches, not shown on FIG. 13, each connected between a respective multiplexing switch 520 and ground in a fashion similar to that shown in FIGS. 2 and 6.

Note that the particular embodiments of the system and method of the present invention described hereinabove are by way of example only, and alternative embodiments of many elements and steps can be employed in particular applications of the invention as would be evident for those skilled in the art.

For example, the important functionality provided by the multiplexing switch 120 and the input switch 160 is to sequentially connect one of the plurality of input terminals N at a time to a single output switch terminal 125 in a selected sequence with a low resistance, while connecting with a low resistance the other (N−1) input terminals to a source of a reference potential, for example—ground. The particular embodiments described herein, where this functionality is implemented using an NPST switch 120 and an N-SPST switch 160, is currently preferred because of commercial availability of such low-resistance analog CMOS switches with serial control interfaces wherein the number of required control lines do not scale with the number of photocurrent signals to multiplex. However, this switching functionality can potentially be embodied using different switch combinations, including but not limited to a single switch having the aforedescribed functionality and a plurality of N SPDT switches, depending on particular application and component availability.

Of course numerous other embodiments may be envisioned without departing from the spirit and scope of the invention.

We claim:

1. A current multiplexing circuit, comprising:
a plurality of input terminals for receiving a plurality of current signals;
a multiplexing switch coupled to the plurality of input terminals for sequentially coupling each of the plurality of input terminals to an output switch terminal for transmitting one of the current signals at a time;
an operational amplifier having a differential input coupled to the output switch terminal and to a reference potential, so as to amplify each of the electrical current signals in a selected sequence while maintaining the output switch terminal at substantially the reference potential.

2. A current multiplexing circuit of claim 1, comprising an input switch for selectively coupling to the reference potential those of the plurality of the input terminals that are not coupled to the output switch terminal by the multiplexing switch.

3. A current multiplexing circuit of claim 2, wherein the reference potential is ground.

4. A current multiplexing circuit of claim 2, wherein the operational amplifier includes a feedback circuit so as to form a trans-impedance amplifier.

5. A current multiplexing circuit of claim 4, wherein the feedback circuit comprises a double pole single throw (DPST) switch for providing a switchable gain to the trans-impedance amplifier.

6. A current multiplexing circuit of claim 4, wherein one of two output terminal of the DPST switch is coupled to the reference potential for reducing current leakage of the DPST switch.

7. A current multiplexing circuit of claim 2 further comprising a plurality of current sources coupled to the plurality of input terminals for generating the plurality of current signals.

8. A current multiplexing circuit of claim 2, further comprising a controller for controlling the multiplexing and input switches.

9. A current multiplexing circuit of claim 1, wherein the multiplexing switch comprises an analog N pole single throw (NPST) switch, where N is an integer equal or greater than the number of current signals.

10. A current multiplexing circuit of claim 9, wherein the NPST switch comprises a monolithic CMOS integrated circuit having an ‘ON’ resistance no greater than 10 Ohm.

11. A current multiplexing circuit of claim 2, wherein the input switch comprises a plurality of single pole single throw (SPST) switches having an ‘ON’ resistance no greater than 10 Ohm.

12. A current multiplexing circuit of claim 11, wherein the plurality of SPST switches is in the form of a single CMOS integrated circuit having a common control interface.

13. A current monitor comprising
a current multiplexing circuit according to claim 2, and further comprising:
an analog to digital converter (ADC) coupled to an output port of the operational amplifier for providing a digital signal in response to an analog electrical signal from the operational amplifier; and,
a controller coupled to the ADC for receiving the digital signal and for providing an output signal indicative of each of the plurality of current signals transmitted by the multiplexing switch in the selected sequence.

14. A current monitor according to claim 13, further comprising
control links coupling the controller to the multiplexing and input;
wherein the controller is programmed to generate control signals for controlling the multiplexing switch so as to connect one of the input terminals to the output switch port at a time, and for controlling the input switch so as to connect to the reference potential those of the input terminals that are not currently connected to the output switch terminal of the multiplexing switch.

15. A current monitor according to claim 14, wherein the controller includes memory for storing calibration data comprising an offset value.

16. A current monitor according to claim 15, wherein the controller is programmed to subtract the offset value from the digital signal to obtain the output signal indicative of each of the plurality of current signals transmitted by the multiplexing switch in the selected sequence.

17. A current monitor according to claim 16, wherein the controller is programmed to obtain the offset value from the digital signal recorded when the input switch is switched to connect each of the input terminals to the reference potential, while the multiplexing switch is switched to disconnect all of the input terminals from the output switch terminal.

18. A current monitor according to claim 16, wherein the controller is programmed to obtain the offset value from the digital signal that is recorded when one of the input terminals that is currently connected to the output switch terminal by the multiplexing switch receives a known reference current signal.

19. An optical power monitor for monitoring a plurality of optical signals, comprising
a current monitor according to claim 13; and,
a plurality of photodetectors for receiving the plurality of optical signals and for generating therefrom the plurality of current signals.

20. An optical power monitor of claim 19 wherein the plurality of photodetectors comprises zero-biased photodiodes.

21. A method for monitoring a plurality of current signals using the current multiplexing circuit of claim 2, the method comprising:
providing the plurality of current signals to the plurality of input terminals;
recording a reference signal obtained from an output of the operational amplifier when the multiplexing and input switches are in a referencing mode of operation;
operating the multiplexing and input switches to sequentially connect at least some of the input terminals to the output switch terminal; and,
calibrating a signal obtained from the output of the operational amplifier utilising the reference signal to compensate for undesirable leakage currents and/or temperature variations.

22. A method according to claim 21, wherein the referencing mode of operation comprises operating the multiplexing switch so as to substantially disconnect all of the plurality of input terminals from the output switch terminal.

23. A method according to claim 21, wherein the referencing mode of operation comprises:
receiving a known reference current in one of the input terminals;
connecting said one of the input terminals to the output switch terminal; and,
connecting the rest of the input terminals to the reference potential.
